(19) United States
(12) Patent Application Publication
(10) Pub. No.: US 2026/0092815 A1
(43) Pub. Date: Apr. 2, 2026

(54) INFRARED BOLOMETER USING SEMICONDUCTING CARBON NANOTUBES AND METHOD FOR MANUFACTURING THE SAME

(71) Applicant: NEC Corporation, Tokyo (JP)

(72) Inventor: Tomo TANAKA, Tokyo (JP)

(73) Assignee: NEC Corporation, Tokyo (JP)

(21) Appl. No.: 18/951,935

(22) Filed: Nov. 19, 2024

(30) Foreign Application Priority Data
Dec. 12, 2023 (JP) 2023-209069

(51) Int. Cl. G01J 5/22; H10F 30/282

(52) U.S. Cl. CPC G01J 5/22; H10F 30/282

(57) ABSTRACT

To reduce the resistance value of an infrared bolometer using semiconducting carbon nanotubes.

An infrared bolometer comprising:
a source electrode and a drain electrode arranged at a distance from each other;
a carbon nanotube film, which is a light detection part, that is present between the two electrodes and that overlaps at least partially with and is in electrical contact with the two electrodes; and
a gate electrode that is provided above or below the carbon nanotube film via an insulating film.

This application is based upon and claims the benefit of priority from Japanese patent application No. 2023-209069, filed on Dec. 12, 2023, the disclosure of which is incorporated herein in its entirety by reference.

### TECHNICAL FIELD

The present disclosure relates to an infrared bolometer using semiconducting carbon nanotubes and a method for manufacturing the same.

### BACKGROUND ART

A bolometer-type infrared sensor changes the temperature of a light receiving portion as a result of the incident infrared radiation absorbed by the light-receiving part, and detects the radiation intensity of the infrared radiation as an electrical signal from a change in resistance caused by a change in temperature of a material placed on the light-receiving part. Currently, vanadium oxide and amorphous silicon are mainly used as element materials for bolometers. However, vanadium oxide has a problem in that its performance is rate-limited by its low temperature dependence of resistance change (temperature coefficient of resistance (TCR)). Furthermore, amorphous silicon has a high resistance value, and performance that exceeds that of vanadium oxide has not yet been achieved.

In light of this technical background, the use of carbon nanotubes (CNTs), which have a high absolute value of TCR, for the bolometer portion is being considered. For example, Patent Literature 1 describes a semiconductor photodetector element in which a metal portion is provided on the surface of a semiconductor portion having a light receiving region, and a CNT film is provided on the upper surface of the light receiving region and on the upper surface of the metal portion.

### CITATION LIST

### Patent Literature

Patent Literature 1: Japanese patent publication No. 2018-148138

### SUMMARY OF INVENTION

### Technical Problem

However, because semiconducting CNTs have a high TCR but a high resistance value, infrared sensors using them in the bolometer section have a problem of low signal-to-noise ratio (S/N). Therefore, in order to put infrared sensors using carbon nanotubes (uncooled CNT infrared sensors) into practical use, it is necessary to lower the resistance in addition to improving the TCR.

In view of the above-mentioned problems, an object of the present disclosure is to reduce the resistance value of an infrared bolometer using semiconducting carbon nanotubes.

### Solution to Problem

In order to achieve the above-mentioned object, the infrared bolometer of the present disclosure is an infrared bolometer comprising:
a source electrode and a drain electrode arranged at a distance from each other;
a carbon nanotube film, which is a light detection part, that is present between the two electrodes and that overlaps at least partially with and is in electrical contact with the two electrodes; and
a gate electrode that is provided above or below the carbon nanotube film via an insulating film.

### Advantageous Effect of Invention

According to the present disclosure, it is possible to provide an infrared bolometer comprising a low resistance value and a method for manufacturing the same.

### BRIEF DESCRIPTION OF DRAWINGS

FIG. 1A is a cross-sectional view showing an example of the structure of an infrared bolometer of the present disclosure, in which a gate electrode is formed under a carbon nanotube film via a first insulating film.

FIG. 1B is a cross-sectional view showing one example of the structure of an infrared bolometer of the present disclosure, in which a gate electrode is formed under a carbon nanotube film via a first insulating film.

FIG. 1C is a cross-sectional view showing one example of the structure of an infrared bolometer of the present disclosure, in which a gate electrode is formed under a carbon nanotube film via a first insulating film.

FIG. 1D is a cross-sectional view showing one example of the structure of an infrared bolometer of the present disclosure, in which a gate electrode is formed under a carbon nanotube film via a first insulating film.

FIG. 1E is a cross-sectional view showing one example of the structure of an infrared bolometer of the present disclosure, in which a gate electrode is formed under a carbon nanotube film via a first insulating film.

FIG. 2 is a cross-sectional view showing a method for manufacturing the bolometer of FIG. 1.

FIG. 3 is cross-sectional and plan views showing the infrared bolometer of the present disclosure, in which a gate electrode is formed under a carbon nanotube film via a first insulating film.

FIG. 4 is a cross-sectional view showing a variation of the bolometer of the present disclosure.

FIG. 5 is cross-sectional and plan views showing the infrared bolometer of the present disclosure, in which a gate electrode is formed under a carbon nanotube film via a first insulating film.

FIG. 6 is a cross-sectional view showing a variation of the bolometer of the present disclosure.

FIG. 7 is cross-sectional and plan views showing the infrared bolometer of the present disclosure, in which a gate electrode is formed under a carbon nanotube film via a first insulating film.

FIG. 8 is a cross-sectional view showing a variation of the bolometer of the present disclosure.

FIG. 9 is cross-sectional and plan views showing the infrared bolometer of the present disclosure, in which a gate electrode is formed under a carbon nanotube film via a first insulating film.

FIG. 10 is a cross-sectional view showing a variation of the bolometer of the present disclosure.

FIG. 11 is a cross-sectional view showing one example of the structure of an infrared bolometer of the present disclosure, in which a gate electrode is formed on a carbon nanotube film via a second insulating film.

FIG. 12 is a cross-sectional view showing a method for manufacturing the bolometer of FIG. 11.

FIG. 13 is cross-sectional and plan views showing the infrared bolometer of the present disclosure, in which a gate electrode is formed on a carbon nanotube film via a second insulating film.

FIG. 14 is cross-sectional and plan views showing the infrared bolometer of the present disclosure, in which a gate electrode is formed on a carbon nanotube film via a second insulating film.

FIG. 15 is cross-sectional and plan views showing the infrared bolometer of the present disclosure, in which a gate electrode is formed on a carbon nanotube film via a second insulating film.

FIG. 16 is cross-sectional and plan views showing the infrared bolometer of the present disclosure, in which a gate electrode is formed on a carbon nanotube film via a second insulating film.

FIG. 17 is cross-sectional and plan views showing the infrared bolometer of the present disclosure, in which a gate electrode is formed on a carbon nanotube film via a second insulating film.

FIG. 18 is cross-sectional and plan views showing the infrared bolometer of the present disclosure, in which a gate electrode is formed on a carbon nanotube film via a second insulating film.

FIG. 19A is cross-sectional and plan views of the bolometers of Example 1 and Comparative Example 1.

FIG. 19B is cross-sectional and plan views of the bolometers of Example 1 and Comparative Example 1.

FIG. 20 is a diagram showing current/voltage curves of the bolometers of Example 1 and Comparative Example 1.

### DESCRIPTION OF EMBODIMENTS

Hereinafter, embodiments of the present disclosure will be described with reference to the drawings. In the following embodiments, parts that are the same or equivalent to each other will be denoted by the same reference numerals.

### <Infrared Bolometer>

The infrared bolometer of the present disclosure comprises:
a source electrode and a drain electrode arranged at a distance from each other;
a carbon nanotube film, which is a light detection part, that is present between the two electrodes and that overlaps at least partially with and is in electrical contact with the two electrodes; and
a gate electrode that is provided above or below the carbon nanotube film via an insulating film.

In the infrared bolometer of the present disclosure, a gate electrode is placed above or below the carbon nanotube film, which is the light detection unit, via an insulating film, and a gate voltage is applied to the carbon nanotube film, the current flowing through the carbon nanotube film is increased, thereby reducing the resistance value of the infrared bolometer.

In the present disclosure, “above or below the carbon nanotube film” includes above or below the carbon nanotube film present between the source electrode and the drain electrode, as well as above or below the portion where the source electrode or drain electrode and the carbon nanotube film overlap. Herein, “above the portion where the source electrode or drain electrode and the carbon nanotube film overlap” means “above the source electrode or drain electrode provided on the carbon nanotube film” or “above the carbon nanotube film provided on the source electrode or drain electrode”; and “below the portion where the source electrode or drain electrode and the carbon nanotube film overlap” means “below the carbon nanotube film provided under the source electrode or drain electrode” or “below the source electrode or drain electrode provided under the carbon nanotube film”.

There are two types of carbon nanotubes, i.e., semiconducting and metallic, but the carbon nanotube film of the present disclosure generally comprises 67 mass % or more of semiconducting carbon nanotubes of the total amount of carbon nanotubes, and the film as a whole exhibits semiconducting properties. The semiconducting type may be either p-type or n-type. Since p-type semiconducting carbon nanotubes are easier to manufacture than n-type semiconducting carbon nanotubes, the following description will focus on p-type.

In this description, of a pair of electrodes in contact with the carbon nanotube film at a distance, the electrode that provides a ground potential (0 V; reference potential) is referred to as the drain electrode, and the other electrode is referred to as the source electrode. The infrared bolometer of the present disclosure functions as a bolometer by detecting the temperature change in the current between the source electrode and the drain electrode (i.e., the temperature change in the resistance of the carbon nanotube film).

In the following, infrared bolometers will be explained by dividing them into a back-gate type having a structure in which a gate electrode is provided below the carbon nanotube film (i.e., the substrate side) via an insulating film, and a top-gate type having a structure in which a gate electrode is provided above the carbon nanotube film (i.e., the opposite side to the substrate) via an insulating film. The substrate will be described later.

### [1] Infrared Bolometer Having a Gate Electrode Provided Under a Carbon Nanotube Film Via an Insulating Film (Back-Gate Type)

One embodiment of the infrared bolometer of the present disclosure is a back-gate type infrared bolometer in which a gate electrode is formed below the carbon nanotube film via a first insulating film. A typical example of the structure of the infrared bolometer of this embodiment is shown in Figure TA.

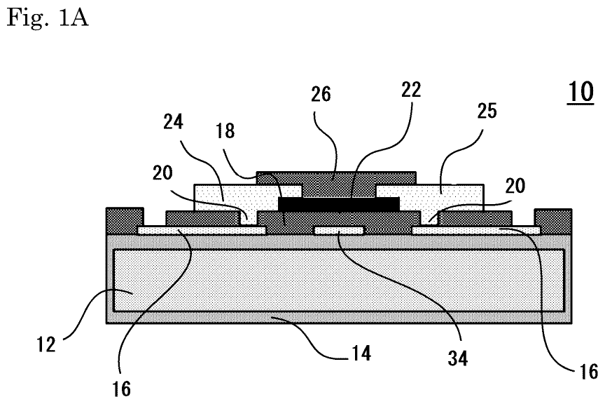

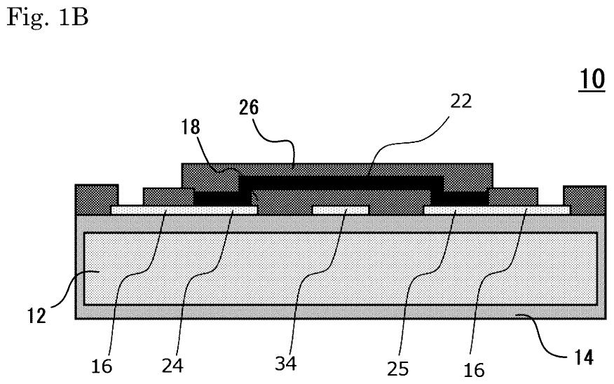

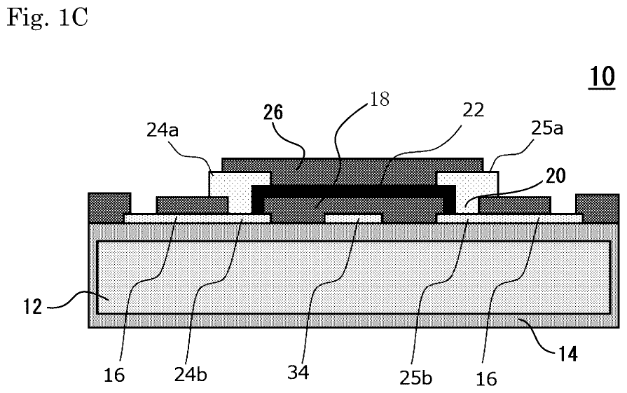

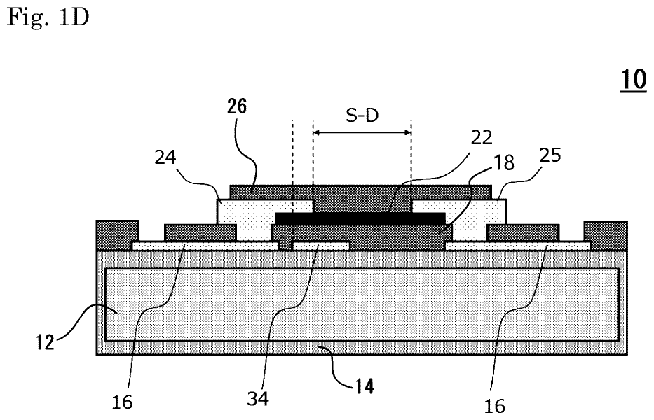

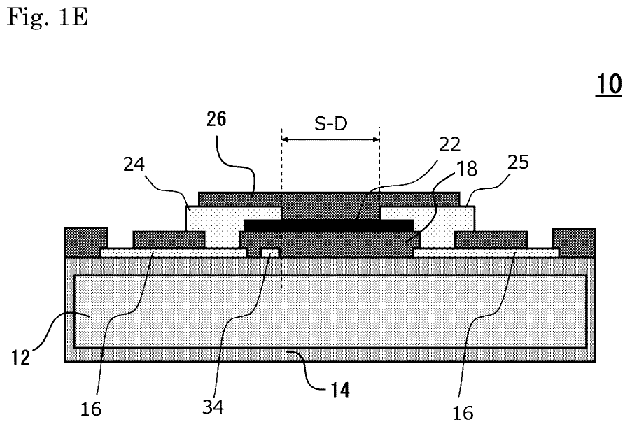

In the bolometer 10 of FIG. 1A, a mirror-cum-gate electrode 34 and wirings 16 are present on a substrate 12 covered with a resin film 14, a first insulating film 18 is present on the mirror-cum-gate electrode 34, and a carbon nanotube film 22 is present on the first insulating film 18. Contact holes 20 are present in the insulating film 18. Two contact electrodes, i.e., a source electrode 24 and a drain electrode 25, are present so that the carbon nanotube film 22 and the wirings 16 are in electrical contact via the contact holes 20. The contact electrodes are present so as to cover a part of the carbon nanotube film 22 and a part of the wirings 16. A light absorbing film-cum-protective film 26 is present so as to cover the exposed part of the carbon nanotube film 22.

In the infrared bolometer shown in Figure TA, the carbon nanotube film 22 is electrically connected to a source electrode 24 and a drain electrode 25 provided at a distance from each other. The source electrode 24 and the drain electrode 25 in this example are “contact electrodes” formed by depositing an electrode material after forming the carbon nanotube film. The source electrode 24 and the drain electrode 25 are connected to the wirings 16. In the present application, the source electrode 24 and the drain electrode 25 formed by depositing an electrode material after forming the carbon nanotube film, as in this example, are referred to as a “contact electrode type”.

On the other hand, as shown in FIG. 1B, the carbon nanotube film 22 can also be formed so as to be in direct contact with the previously formed wirings 16, thereby connecting the carbon nanotube film 22 to the wirings 16. In this structure, the source electrode 24 and the drain electrode 25 are the portions of the wirings 16 that are in contact with the carbon nanotube film 22. The source electrode 24 and the drain electrode 25 in this structure are referred to as a “direct contact type.”

As shown in FIG. 1C, the carbon nanotube film 22 is in direct contact with the previously formed wirings 16, and can also be connected to a contact electrode formed by depositing an electrode material after the carbon nanotube film is formed. Therefore, the source electrode 24 and the drain electrode 25 have contact electrode parts (24a, 25a) and direct contact parts (24b, 25b).

In the back-gate type of this embodiment, the gate electrode is present “below the carbon nanotube film”. In FIG. 1A, the entire gate electrode is present in a part of the lower region between the source electrode and the drain electrode, but the gate electrode may be present throughout the entire lower region between the source electrode and the drain electrode. Furthermore, as shown in FIG. 1D and FIG. 1E, a part (see FIG. 1D) or the entirety (see FIG. 1E) of the gate electrode 34 may be present below the source electrode 24 (or the drain electrode 25) outside the source electrode-drain electrode (S-D). However, the gate electrode 34 is present below the carbon nanotube film 22 via an insulating film (back gate), and the source electrode 24 (or the drain electrode 25) is in contact with the carbon nanotube film above the carbon nanotube film 22 (i.e., the opposite side to the gate electrode).

The configuration of the back-gate type is also applicable to a top-gate type described later, and provided that the gate electrode is “above the carbon nanotube film,” it may be present over part or all of the upper portion between the source electrode and the drain electrode, and further, part or all of the gate electrode 34 may be located outside the source electrode-drain electrode space (S-D) and above the source electrode 24 (or drain electrode 25).

In a bolometer having the above structure, when a specific potential is applied to the gate electrode while a voltage is applied between the source and drain, carriers are induced in the carbon nanotube film, which is believed to result in an increase in the current between the source and drain. In addition, when the gate electrode is located below the source electrode 24 (or the drain electrode 25) (FIG. 1D and FIG. 1E), when a specific potential is applied to the gate electrode, the Schottky barrier between the source electrode 24 (or the drain electrode 25) and the carbon nanotube film is changed, which is believed to increase the current between the source electrode and drain electrode.

The voltage applied to the gate electrode 34 can be different from that of the source electrode 24 and the drain electrode 25, but the gate electrode 34 may be short-circuited to either the source electrode 24 or the drain electrode 25. Short-circuiting the gate electrode 34 to either the source electrode 24 or the drain electrode 25 is more preferable because it facilitates integration as a detector. In particular, a back-gate type bolometer is particularly advantageous in terms of integration because a pattern in which the gate electrode and the source electrode or drain electrode are short-circuited can be easily formed, as shown in the embodiment described below. Note that when the gate electrode is present only below the source electrode (FIG. 1E), it is preferable to apply a potential different from that of the source electrode to the gate electrode, and therefore when the gate electrode is short-circuited, it is preferable to short-circuit it with the drain electrode. Also, when a part of the gate electrode is present below the source electrode (FIG. 1D), it is usually preferable to short-circuit the gate electrode with the drain electrode. Conversely, when the gate electrode is present below the drain electrode, it is preferable to short-circuit the gate electrode with the source electrode.

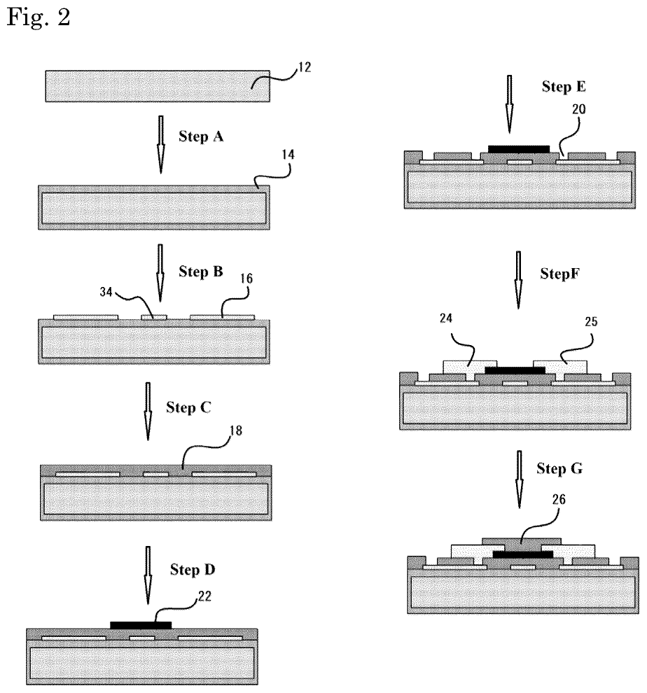

A specific example of each component of the infrared bolometer 10 shown in FIG. 1A will be described together with a manufacturing method shown in FIG. 2.

### [Step A]

A substrate, at least a surface of the substrate on which an element is formed being insulating, is prepared.

The material constituting the substrate 12 may be an inorganic material or an organic material, and any material used in the art may be used without any particular limitation. Inorganic materials include, but are not limited to, glass, Si, SiO₂ and SiN. Organic materials include, but are not limited to, plastics and rubber such as polyimide, polyethylene, polypropylene, polystyrene, polyvinyl chloride, polyethylene terephthalate, acrylonitrile styrene resin, acrylonitrile butadiene styrene resin, fluororesin, methacrylic resin, and polycarbonate.

The resin film 14 is made of a resin with high thermal insulation (low thermal conductivity). By covering the substrate surface with a resin with high thermal insulation, it is possible to suppress the dissipation of heat from the carbon nanotube film. The thermal conductivity of the resin constituting the resin film is generally 0.3 W/mK or less, preferably 0.15 W/mK or less, and more preferably 0.1 W/mK or less in some cases. Since a lower thermal conductivity is preferable, the lower limit is not particularly limited, but is, for example, 0.02 W/mK or more, for example, 0.05 W/mK or more. In particular, it is preferable that the thermal conductivity of the resin film at least in the vertical direction (i.e., the lamination direction) is within the above range. In the present specification, the thermal conductivity can be a value obtained at 25° C. according to a standard method (ASTM C177, ASTM E1461, etc.).

The resin used for the resin film is not particularly limited, but may be parylene. Parylene is a general term for paraxylylene-based polymers, and has a structure in which benzene rings are linked via CH₂. Examples of parylene include those formed from a dimer represented by the following formula:

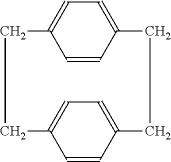 [SMILES: c1cc2ccc1CCc1ccc(cc1)CC2]

In the above formula, at least one hydrogen atom of at least one benzene ring may be substituted with a halogen atom. Examples of halogen include fluorine (F), chlorine (Cl), bromine (Br), and iodine (I), and chlorine is preferred. The number of substitutions by halogen is 8 or less, preferably 6 or less, and more preferably 4 or less.

Parylene includes Parylene N, Parylene C, Parylene D, Parylene HT, and ParyFree, among which Parylene C (thermal conductivity: 0.084 (W/mK)) is the most suitable because it has the lowest thermal conductivity. Parylene is chemically stable and has excellent moisture, chemical, and insulation barrier properties. Parylene coating also has excellent temperature stability, mechanical properties, and tensile strength.

The method of forming the resin film is not particularly limited and can be appropriately selected according to the resin used. For example, when parylene is used, a parylene film can be formed by coating parylene on a substrate using a vacuum deposition apparatus. Specifically, when a solid dimer is heated under vacuum, it vaporizes and becomes a dimer gas. This gas is thermally decomposed to cleave the dimer and become a monomer form. In a deposition chamber at room temperature, this monomer gas polymerizes on all surfaces to form a thin and transparent polymer film. If necessary, the substrate may be pretreated, cleaned, and areas that should not be deposited may be masked before the deposition process.

### [Step B]

A gate electrode 34 (and wirings 16, if necessary) is formed on the substrate. For the gate electrode and wirings, for example, a single metal such as titanium, gold, platinum, aluminum, copper, silver, tungsten, cobalt, or an alloy containing at least one of these metals can be used alone or in combination. In consideration of the adhesive and bonding properties with the insulating film 18, source electrode 24, and gate electrode 25 described later, a combination of two or more metals, such as stacking gold on titanium, may be used. The material of the gate electrode and wirings may be the same as that of the source electrode and drain electrode described later, or a different material may be used. The gate electrode and wirings can be formed by patterning with a metal mask or the like as necessary, followed by deposition or printing.

The gate electrode can also serve as a mirror. The mirror is a layer for reflecting light that has not been absorbed by the carbon nanotube film 22 and has been transmitted therethrough, and for re-absorbing the light in the carbon nanotube film 22. Therefore, the mirror is provided on the opposite side of the carbon nanotube film 22 to the light incident side. In addition, it is preferable to place the mirror at a position where the distance between the carbon nanotube film and the mirror is d=λ/4, taking into consideration the wavelength λ of the light to be absorbed. As the mirror, any material that is used as a light reflecting layer in a bolometer can be used without any restrictions, and generally includes metals such as titanium, gold, silver, and aluminum, and can be formed by deposition, sputtering, plating, and the like. The thickness of the mirror is not particularly limited, but is preferably 0.1 to 5 μm, and more preferably 0.5 to 1 μm.

### [Step C]

A first insulating film 18 is formed on the gate electrode. The material of the insulating film is not particularly limited, but examples include silicon oxide (SiO₂) and silicon nitride film (SiN). The method of forming the insulating film is not particularly limited, and can be appropriately selected according to the material used. Since the insulating film 18 becomes a gate insulating film, it can have a thickness equivalent to that of a gate insulating film in a metal oxide semiconductor field effect transistor (MOSFET), for example, preferably 1 nm to 1 μm, more preferably 5 nm to 200 nm.

### [Step D]

A carbon nanotube film 22 is formed on the first insulating film. The carbon nanotube film is made up of a plurality of carbon nanotubes, is preferably a thin film having a network structure, and functions as a bolometer film.

The thickness of the carbon nanotube film is not particularly limited, but is, for example, 1 nm or more, for example, several nm to 100 μm, preferably 10 nm to 10 μm, more preferably 50 nm to 1 μm. In one embodiment, it is preferably 20 nm to 500 nm, more preferably 50 nm to 200 nm. When the thickness of the carbon nanotube film is 1 nm or more, a good light absorption rate can be obtained. In addition, it is preferable that the thickness of the carbon nanotube film is 1 μm or less, preferably 500 nm or less, from the viewpoint of simplifying the manufacturing method. In addition, if the carbon nanotube film is too thick, the contact electrode deposited from above may not be in sufficient contact with the carbon nanotubes below the carbon nanotube film, and the effective resistance value may become high, but if it is within the above range, the increase in the resistance value can be suppressed. In addition, when the thickness of the carbon nanotube film is within the above-mentioned range of 10 nm to 1 μm, it is also preferable in that the printing technology can be suitably applied as a manufacturing method of the carbon nanotube film. The thickness of the carbon nanotube film can be obtained as the average value of the thicknesses measured at any 10 points of the carbon nanotube film.

The density of the carbon nanotube film is not particularly limited, but may be, for example, 0.3 g/cm³ to 1.4 g/cm³, preferably 0.8 g/cm³ to 1.3 g/cm³, and more preferably 1.1 g/cm³ to 1.2 g/cm³. When the density of the carbon nanotube film is 0.3 g/cm³ or more, a good light absorption rate can be obtained. When the density of the carbon nanotube film is 0.5 g/cm³ or more, a sufficient light absorption rate can be obtained without providing a mirror (light reflecting layer) or a light absorbing film, and it is preferable in that the element structure can be simplified. The density of the carbon nanotube film can be calculated from the weight, area, and thickness of the carbon nanotube film obtained above.

In addition to the above-mentioned components, the carbon nanotube film may comprise, as appropriate, negative thermal expansion materials, ion conductive agents (surfactants, ammonium salts, inorganic salts), resins and organic binders, which will be described later.

The carbon nanotube content in the carbon nanotube film can be selected as appropriate, but preferably, 0.1 mass % or more is effective based on the total mass of the carbon nanotube film, and more preferably, 1 mass % or more is effective. For example, 30 mass % or even 50 mass % or more is preferable, and in some cases 60 mass % or more may be preferable.

An example of a method for producing a carbon nanotube film is described in detail below.

A dispersion liquid in which carbon nanotubes are dispersed is applied onto insulating film 18, dried, and optionally heat-treated to form carbon nanotube film 22.

The carbon nanotube dispersion liquid preferably comprises a surfactant in addition to the carbon nanotubes. The surfactant contained in the carbon nanotube dispersion is preferably a nonionic surfactant. Unlike ionic surfactants, nonionic surfactants have a weak interaction with carbon nanotubes and can be easily removed after the dispersion liquid is provided on a substrate. Therefore, a stable carbon nanotube conductive path can be formed and an excellent TCR value can be obtained. In addition, a nonionic surfactant with a long molecular length is preferable because the distance between the carbon nanotubes becomes large when the dispersion is provided on a substrate and the carbon nanotubes are less likely to re-aggregate after evaporation of water, and therefore the network state can be maintained.

The nonionic surfactant can be appropriately selected, but it is preferable to use one or more nonionic surfactants composed of a non-ionized hydrophilic portion and a hydrophobic portion such as an alkyl chain, such as a nonionic surfactant having a polyethylene glycol structure represented by polyoxyethylene alkyl ether, or an alkyl glucoside nonionic surfactant. As such a nonionic surfactant, polyoxyethylene alkyl ether is preferably used. The alkyl portion may comprise one or more unsaturated bonds. In particular, polyoxyethylene (23) lauryl ether, polyoxyethylene (20) cetyl ether, polyoxyethylene (20) stearyl ether, polyoxyethylene (10) oleyl ether, polyoxyethylene (10) cetyl ether, polyoxyethylene (10) stearyl ether, polyoxyethylene (20) oleyl ether and polyoxyethylene (100) stearyl ether are more preferred. In addition, N,N-bis[3-(D-gluconamido)propyl]deoxycholamide, n-dodecyl β-D-maltoside, octyl β-D-glucopyranoside, and digitonin can also be used.

As a nonionic surfactant, polyoxyethylene sorbitan monostearate (molecular formula: C₆₄H₁₂₆O₂₆, product name: Tween 60, manufactured by Sigma-Aldrich Co., Ltd., etc.), polyoxyethylene sorbitan trioleate (molecular formula: C₂₄H₄₄O₆, product name: Tween 85, manufactured by Sigma-Aldrich Co., Ltd., etc.), octylphenol ethoxylate (molecular formula: C₁₄H₂₂O(C₂H₄O)ₙ, n=1 to 10, product name: Triton X-100, manufactured by Sigma-Aldrich Co., Ltd., etc.), polyoxyethylene (40) isooctylphenyl ether (molecular formula: C₈H₁₇C₆H₄O(CH₂CH₂O)₄₀H, product name: Triton X-405, manufactured by Sigma-Aldrich Co., Ltd., etc.), poloxamer (molecular formula: C₅H₁₀O₂, product name: Pluronic, manufactured by Sigma-Aldrich Co., Ltd., etc.), polyvinylpyrrolidone (molecular formula: (C₆H₉NO)n, n=5 to 100, manufactured by Sigma-Aldrich Co., Ltd., etc.) can also be used.

The concentration of the surfactant in the carbon nanotube dispersion liquid can be appropriately controlled, and is preferably about the critical micelle concentration to 5% by mass, more preferably 0.001% to 3% by mass, and particularly preferably 0.01 to 1% by mass in order to suppress re-aggregation after application. If the concentration is less than the critical micelle concentration, dispersion is not possible, which is not preferable. In the present specification, the critical micelle concentration (CMC) refers to the concentration at which the surface tension becomes inflection when the surface tension is measured at atmospheric pressure and 25° C. using a surface tensiometer such as a Wilhelmy surface tensiometer while varying the concentration of the surfactant aqueous solution.

The dispersion medium for the carbon nanotube dispersion liquid is not particularly limited as long as it can disperse and suspend the carbon nanotubes. Examples of the dispersion medium include water, heavy water, an organic solvent, and a mixture of these, and water is preferred.

The method for obtaining the carbon nanotube dispersion liquid is not particularly limited, and a conventionally known method can be applied. For example, a carbon nanotube mixture, a dispersion medium, and a nonionic surfactant are mixed to prepare a solution comprising carbon nanotubes, and the solution is ultrasonically treated to disperse the carbon nanotubes, to prepare a carbon nanotube dispersion (micelle dispersion solution). In addition to or instead of the ultrasonic treatment, a carbon nanotube dispersion method using mechanical shearing force may be used. Mechanical shearing may be performed in the gas phase. In the micellar dispersion aqueous solution of carbon nanotubes and nonionic surfactant, it is preferable that the carbon nanotubes are isolated. Therefore, if necessary, ultracentrifugation may be used to remove bundles, amorphous carbon and impurity catalysts. During dispersion, the carbon nanotubes can be cut, and the length of the carbon nanotubes can be controlled by changing the crushing conditions, ultrasonic output, and ultrasonic treatment time. For example, untreated carbon nanotubes can be pulverized with tweezers and a ball mill to control the aggregate size. After these processes, the length of the carbon nanotubes can be controlled to 100 nm to 5 μm by using an ultrasonic homogenizer at an output of 40 to 600 W, or in some cases 100 to 550 W, at 20 to 100 KHz for a processing time of 1 to 5 hours, preferably 1 to 3 hours. If the processing time is shorter than 1 hour, the nanotubes may hardly disperse and may retain their original length depending on the conditions. From the viewpoint of shortening the dispersion processing time and reducing costs, a processing time of 3 hours or less is preferable.

By dispersing and cutting the carbon nanotubes, surface functional groups are generated on the surface or ends of the carbon nanotubes. The functional groups generated include carboxyl groups, carbonyl groups and hydroxyl groups. In the case of treatment in a liquid phase, carboxyl groups and hydroxyl groups are generated, and in the case of treatment in a gas phase, carbonyl groups are generated.

Carbon nanotubes can be separated, for example, by the electric field induced layer formation method (ELF method: see, for example, K. Ihara et al. J. Phys. Chem. C. 2011, 115, 22827-22832, and Japanese Patent No. 5717233, which are incorporated herein by reference). An example of a separation method using the ELF method will be described. Carbon nanotubes, preferably single-walled carbon nanotubes, are dispersed by using a nonionic surfactant, and the dispersion liquid is placed in a vertical separation device, and a voltage is applied to the electrodes arranged above and below to separate the nanotubes by carrier-free electrophoresis. The mechanism of separation can be estimated, for example, as follows. When carbon nanotubes are dispersed by using a nonionic surfactant, the micelles of semiconducting carbon nanotubes have a negative zeta potential, while the micelles of metallic carbon nanotubes have the opposite (positive) zeta potential (in recent years, it is also believed that they have a slightly negative zeta potential or are almost uncharged). Therefore, when an electric field is applied to the carbon nanotube dispersion liquid, the semiconducting carbon nanotube micelles electrophoretically move toward the anode (+) and the metallic carbon nanotube micelles electrophoretically move toward the cathode (−) due to the difference in zeta potential. Finally, a layer of concentrated semiconducting carbon nanotubes near the anode and a layer of concentrated metallic carbon nanotubes near the cathode are formed in the separation tank. The voltage for separation can be set appropriately taking into consideration the composition of the dispersion medium and the charge amount of the carbon nanotubes, but is preferably 1 V to 200 V, more preferably 10 V to 200 V. From the viewpoint of shortening the separation time, 100 V or more is preferable. Also, from the viewpoint of suppressing the generation of bubbles during separation and maintaining separation efficiency, 200 V or less is preferable. The purity can be improved by repeating the separation. The dispersion liquid after separation may be reset to the initial concentration and the same separation operation may be performed. The purity can be further increased by repeating the separation.

The above-mentioned carbon nanotube dispersion/cutting step and separation step can provide a dispersion liquid in which semiconducting carbon nanotubes having a desired diameter and length are concentrated. In the present specification, the carbon nanotube dispersion liquid in which semiconducting carbon nanotubes are concentrated may be referred to as a “semiconducting carbon nanotube dispersion liquid”. The semiconducting carbon nanotube dispersion liquid obtained by the separation step means a dispersion liquid comprising semiconducting carbon nanotubes in an amount of generally 67% by mass or more, preferably 70% by mass or more, more preferably 80% by mass or more, particularly preferably 90% by mass or more, more preferably 95% by mass or more, and even more preferably 99% by mass or more (the upper limit may be 100% by mass) of the total amount of carbon nanotubes. The tendency of separation of metallic and semiconducting carbon nanotubes can be analyzed by microscopic Raman spectroscopy and ultraviolet-visible-near infrared absorptiometry.

After the above-mentioned carbon nanotube dispersion/cutting step and before the separation step, a centrifugation treatment may be performed to remove bundles, amorphous carbon, and metal impurities from the carbon nanotube dispersion liquid. The centrifugal acceleration can be adjusted as appropriate, but is preferably 10,000×g to 500,000×g, more preferably 50,000×g to 300,000×g, and may be 100,000×g to 300,000×g in some cases. The centrifugation time is preferably 0.5 hours to 12 hours, more preferably 1 to 3 hours. The centrifugation temperature can be adjusted as appropriate, but is preferably 4° C. to room temperature, more preferably 10° C. to room temperature.

The method for applying the carbon nanotube dispersion liquid to the insulating film 18 is not particularly limited, and examples thereof include a dropping method, spin coating, printing, inkjet, spray coating and dip coating. From the viewpoint of reducing manufacturing costs, a printing method is preferable. Examples of the printing method include coating (dispenser and inkjet), transfer (microcontact printing and gravure printing).

The carbon nanotube dispersion liquid applied to the insulating film is dried and heat-treated to remove the surfactant and the solvent, thereby forming the carbon nanotube film 22. The temperature of the heat treatment can be appropriately set to a temperature equal to or higher than the decomposition temperature of the surfactant, but is preferably 150 to 500° C., more preferably 200 to 500° C., for example 200 to 400° C. The temperature of the heat treatment of 200° C. or higher is more preferable because it is easier to suppress the residue of the decomposed product of the surfactant. Also, The temperature of the heat treatment of 500° C. or lower, for example 400° C. or lower, is preferable because it is possible to suppress the deterioration of the substrate and other components. Also, it is possible to suppress the decomposition and size change of the carbon nanotubes, the detachment of functional groups, and the like.

Carbon nanotubes can form, for example, parallel wire, fiber, network, or other structures, but preferably form a three-dimensional network structure which is less prone to aggregation and provides uniform conductive paths.

The carbon nanotubes may be single-walled, double-walled or multi-walled carbon nanotubes, but single-walled or several-walled (e.g., two-walled or three-walled) carbon nanotubes are preferred, and single-walled carbon nanotubes are more preferred. The carbon nanotubes preferably comprise 80% by mass or more of single-walled carbon nanotubes, and more preferably comprise 90% by mass or more (including 100% by mass).

The carbon nanotube film is preferably made of semiconducting carbon nanotubes having a large band gap and carrier mobility. The content of semiconducting carbon nanotubes, preferably semiconducting single-walled carbon nanotubes, in the carbon nanotubes is generally 67% by mass or more, preferably 70% by mass or more, more preferably 80% by mass or more, particularly preferably 90% by mass or more, more preferably 95% by mass or more, and even more preferably 99% by mass or more (including 100% by mass).

The diameter of the carbon nanotube is not particularly limited, but from the viewpoint of increasing the band gap and improving the TCR, it is preferably between 0.6 and 1.5 nm, more preferably between 0.6 and 1.2 nm, and even more preferably between 0.7 and 1.1 nm. In one embodiment, the diameter of the carbon nanotube may be particularly preferable for the diameter to be 1 nm or less. If the diameter of the carbon nanotube is 0.6 nm or more, the production of the carbon nanotube is easier. If the diameter of the carbon nanotube is 1.5 nm or less, it is easier to maintain the band gap in an appropriate range, and a high TCR can be obtained.

In the present specification, the diameter of the carbon nanotubes means that the diameters of about 100 points of the carbon nanotubes on the heat insulating layer or in the formed thin film are measured using an atomic force microscope (AFM), and 60% or more, preferably 70% or more, in some cases more preferably 80% or more, and more preferably 100% of the diameters are within the range of 0.6 to 1.5 nm. Preferably, 60% or more, preferably 70% or more, in some cases more preferably 80% or more, and more preferably 100% of the diameters are within the range of 0.6 to 1.2 nm, and even more preferably 0.7 to 1.1 nm. In one embodiment, 60% or more, preferably 70% or more, in some cases more preferably 80% or more, and more preferably 100% of the diameters are within the range of 0.6 to 1 nm.

The length of the carbon nanotubes is not particularly limited, but is preferably between 100 nm and 5 μm because it is easy to disperse and has excellent coating properties. From the viewpoint of the electrical conductivity of the carbon nanotubes, the length is preferably 100 nm or more. If the length of the carbon nanotubes is 5 μm or less, aggregation on the heat insulating layer and/or during film formation is easily suppressed. The length of the carbon nanotubes is more preferably 500 nm to 3 μm, and even more preferably 700 nm to 1.5 μm.

In the present specification, the length of carbon nanotubes means that at least 100 tubes are observed and counted using an atomic force microscope (AFM) to measure the distribution of the lengths of the carbon nanotubes, and 60% or more, preferably 70% or more, in some cases more preferably 80% or more, and more preferably 100% of the tubes are in the range of 100 nm to 5 μm. Preferably, 60% or more, preferably 70% or more, in some cases more preferably 80% or more, and more preferably 100% of the tubes are in the range of 500 nm to 3 μm. More preferably, 60% or more, preferably 70% or more, in some cases more preferably 80% or more, and more preferably 100% of the tubes are in the range of 700 nm to 1.5 μm.

When the diameter and length of the carbon nanotube are within the above ranges, the effect of semiconductivity becomes large and a large current value can be obtained, so that when used as a bolometer film, a high TCR value is likely to be obtained.

The carbon nanotubes may be heat-treated in an inert atmosphere in a vacuum to remove surface functional groups, impurities such as amorphous carbon and catalysts. The heat treatment temperature can be appropriately selected, but is preferably 800 to 2000° C., more preferably 800 to 1200° C.

### [Step E]

If necessary, contact holes 20 for electrically connecting the wirings 16 and the carbon nanotube film 22 are formed in the insulating film 18. The contact holes may be formed as openings for connecting the source electrode 24 and the drain electrode 25 connected to the carbon nanotube film 22 to wiring, or may be formed as openings for connecting the wirings 16 to the outside.

The shape of the contact holes 20 is not particularly limited, but it is preferable that the shape and size are such that the contact holes 20 can maintain the protective function of the substrate 12 and the resin film 14. The method for forming the contact holes 20 is not particularly limited, but the contact holes 20 can be formed by, for example, mechanical removal or etching.

### [Step F]

If necessary, two contact electrodes, that is, a source electrode 24 and a drain electrode 25, are formed so as to be in contact with the carbon nanotube film 22 and the wirings 16.

The source electrode 24 and the drain electrode 25 may be appropriately selected in consideration of the adhesiveness and the characteristics of the junction formed with the carbon nanotube film 22. For example, a single metal such as titanium, gold, platinum, aluminum, copper, silver, tungsten, or cobalt, or an alloy comprising at least one of these, may be used alone or in combination. The material of the source electrode and the drain electrode may be the same as that of the wiring, or a different material may be used. The height of the source electrode and the drain electrode can be adjusted appropriately, but is preferably 10 nm to 1 mm, more preferably 50 nm to 1 μm, and particularly preferably 50 nm to 200 nm. The distance between the source electrode and the drain electrode is preferably 1 μm to 500 μm, and more preferably 5 to 200 μm for miniaturization. The method of forming the source electrode 24 and the drain electrode 25 is not particularly limited, but they can be formed by, for example, deposition, sputtering, or printing. If necessary, masking of regions where the source electrode and the drain electrode should not be formed may be performed in advance.

### [Step G]

If necessary, a protective film 26 is formed so as to cover the exposed portion of the carbon nanotube film 22. The protective film can have an effect of suppressing doping of the carbon nanotubes due to adsorption of oxygen. As the protective film, any material that is used as a protective film in a bolometer can be used without limitation, and examples of the protective film include silicon nitride (SiN), silicon oxide (SiO₂), resins such as acrylic resins such as parylene, PMMA, and PMMA anisole, epoxy resins, and Teflon (registered trademark) films.

It is also preferable to use a material that functions as a light absorbing film-cum-protective film for the protective film. Such materials are preferably silicon nitride (SiN) and silicon oxide (SiO₂). The light absorbing film has the effect of improving the absorption rate of electromagnetic waves. The thickness of the light absorbing film can be appropriately set depending on the material, but can be, for example, 50 nm to 1 μm.

The manufacturing method of the infrared bolometer 10 shown in FIG. 1A has been described above. In the case of manufacturing a direct contact type (where the source electrode 24 and the drain electrode 25 are in direct contact with the carbon nanotube film 22) as shown in FIG. 1B, when forming the first insulating film 18 on the gate electrode in step C, (i) a part of the wirings 16 (at least the part that will become the source electrode 24 and the drain electrode 25) is masked, (ii) an insulating film is then formed in a region including at least the gate electrode, (iii) the mask is then removed to expose a part of the wirings 16, and (iv) the carbon nanotube film 22 is then formed in step D. As a result, the carbon nanotube film 22 is in direct contact with a part of the wirings 16, and the contact part functions as the source electrode 24 and the drain electrode 25. As another manufacturing method, after forming the insulating film in step C, the insulating film can be removed by etching before forming the carbon nanotube film 22 to expose a portion of the wirings 16 (at least the portion that will become the source electrode 24 and the drain electrode 25), and the carbon nanotube film 22 can be formed in step D.

Furthermore, a structure having contact electrodes and direct contact parts, as shown in FIG. 1C, can be manufactured by first forming a structure in which the carbon nanotube film is in direct contact with a portion of the wiring, and then forming the contact electrode.

### Examples of Back-Gate Type: Embodiments of Infrared Bolometers in which a Gate Electrode is Formed Under a Carbon Nanotube Film Via an Insulating Film

### First Embodiment

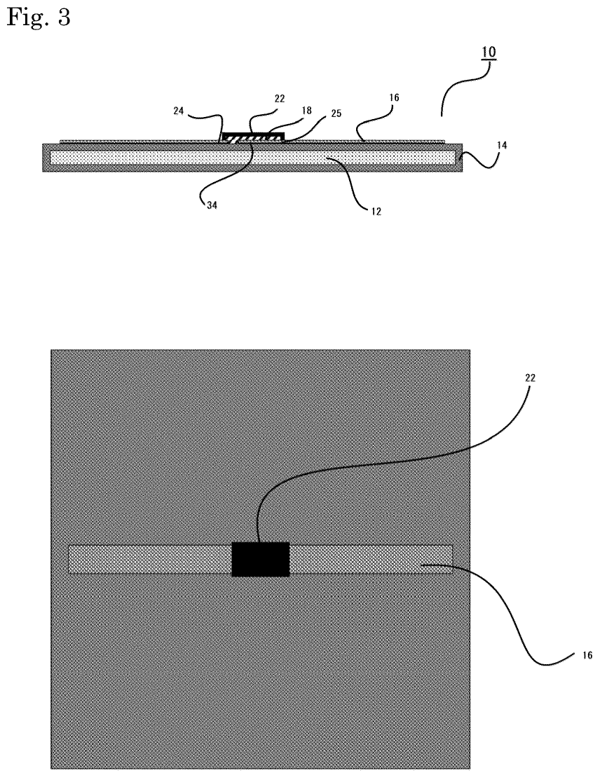

An infrared bolometer 10 according to a first embodiment of the present disclosure will be described with reference to FIG. 3. As shown in FIG. 3, the bolometer of the first embodiment has a mirror-cum-gate electrode 34 and wirings 16 (including a source electrode 24 and a drain electrode 25) formed on a substrate having an insulating surface, and a first insulating film 18 formed thereon. A carbon nanotube film 22, which is a light detection section, is formed on the first insulating film 18.

In the infrared bolometer 10 according to the first embodiment, a mirror-cum-gate electrode 34, which is spatially and electrically insulated from the carbon nanotube film 22, is provided below the carbon nanotube film 22, and a voltage is applied between the source electrode 24 and the drain electrode 25, so that the mirror-cum-gate electrode 34 and the drain electrode 25 are electrically short-circuited. As shown in FIG. 3, the wiring on the drain side as viewed from the power supply terminal side is connected to the drain side end of the carbon nanotube film to form the drain electrode, and is further extended to reach the bottom of the carbon nanotube film to form the gate electrode. In this embodiment, the portions of the wirings 16 that are in contact with the carbon nanotube film 22 serve as a source electrode 24 and a drain electrode 25. The source electrode 24 and the drain electrode 25 may be arranged inversely.

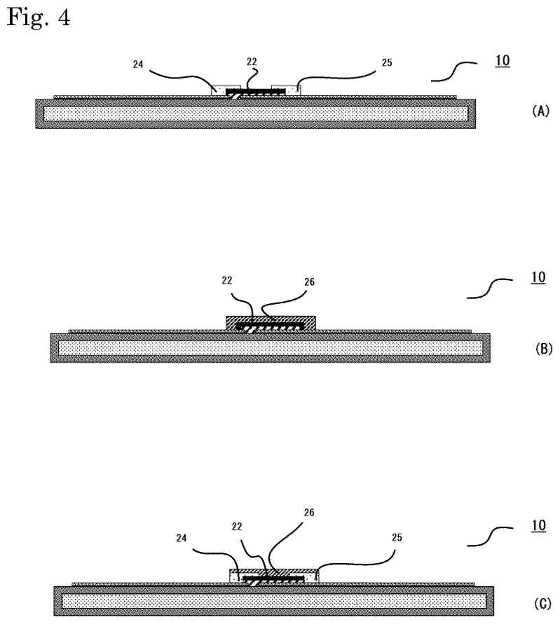

FIG. 4 shows a variation of the infrared bolometer according to the first embodiment of the present disclosure. The infrared bolometer 10 shown in FIG. 4A has a carbon nanotube film 22 that is not in direct contact with the wirings 16 in the infrared bolometer shown in FIG. 3, and has a source electrode 24 and a drain electrode 25 that are contact electrodes. The infrared bolometer 10 shown in FIG. 4B has a protective film 26 formed above the carbon nanotube film 22 in addition to the infrared bolometer shown in FIG. 3. The infrared bolometer 10 shown in FIG. 4C has a carbon nanotube film 22 that is not in direct contact with the wirings 16 in the infrared bolometer shown in FIG. 3, and is connected to the wirings by the source electrode and the drain electrode that are contact electrodes, and additionally has a protective film 26 on the carbon nanotube film 22. The source electrode 24 and the drain electrode 25 may be arranged inversely.

### Second Embodiment

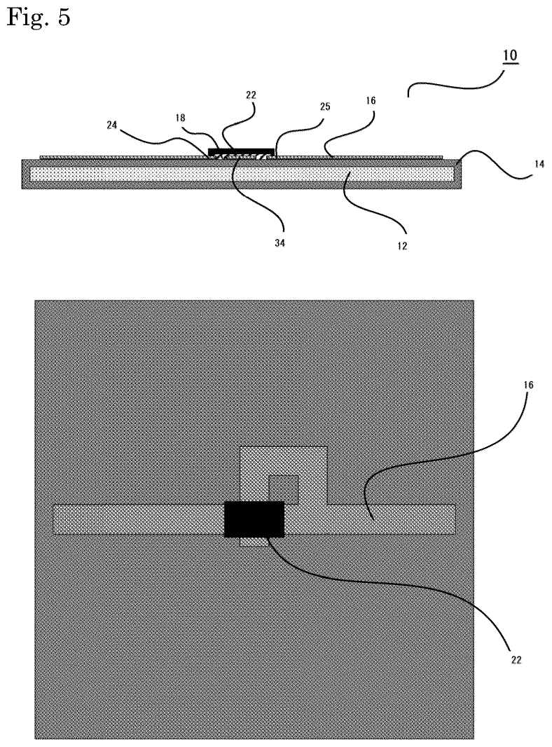

The infrared bolometer 10 according to the second embodiment of the present disclosure will be described with reference to FIG. 5. As shown in FIG. 5, in the bolometer of this embodiment, a mirror-cum-gate electrode 34 and wirings 16 (including a source electrode 24 and a drain electrode 25) are formed on a substrate having an insulating surface, and a first insulating film 18 is formed thereon. A carbon nanotube film 22, which is a light detection part, is formed on the first insulating film 18.

In the infrared bolometer 10 according to the second embodiment, a mirror-cum-gate electrode 34 that is spatially and electrically insulated from the carbon nanotube film 22 is provided below the carbon nanotube film 22, a voltage is applied between the source electrode 24 and the drain electrode 25, and the mirror-cum-gate electrode 34 and the drain electrode 25 are electrically short-circuited. As shown in FIG. 5, the wiring on the drain side when viewed from the power supply terminal side branches off at an angle of 90° before connecting to the drain side end of the carbon nanotube film, and the branched wiring turns at an angle of 180° and extends to the bottom of the carbon nanotube film to form the gate electrode. In this embodiment, the portions of the wirings 16 that are in contact with the carbon nanotube film 22 serve as a source electrode 24 and a drain electrode 25. The source electrode 24 and the drain electrode 25 may be arranged inversely.

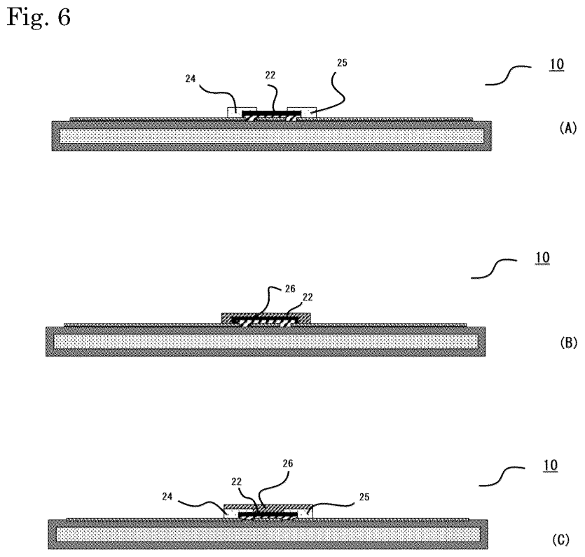

FIG. 6 shows variations of the infrared bolometer according to the second embodiment of the present disclosure. The infrared bolometer 10 shown in FIG. 6A is the same as the infrared bolometer shown in FIG. 5 except that the carbon nanotube film 22 is not in direct contact with the wirings 16, and has a source electrode 24 and a drain electrode 25 which are contact electrodes. The infrared bolometer 10 shown in FIG. 6B has a protective film 26 formed on the carbon nanotube film 22 in addition to the infrared bolometer shown in FIG. 5. The infrared bolometer 10 shown in FIG. 6C is the same as the infrared bolometer shown in FIG. 5 except that the carbon nanotube film 22 is not in direct contact with the wirings 16, and is connected to the wirings by the source electrode 24 and the drain electrode 25 which are contact electrodes, and additionally has a protective film 26 on the carbon nanotube film 22. The source electrode 24 and the drain electrode 25 may be arranged inversely.

### Third Embodiment

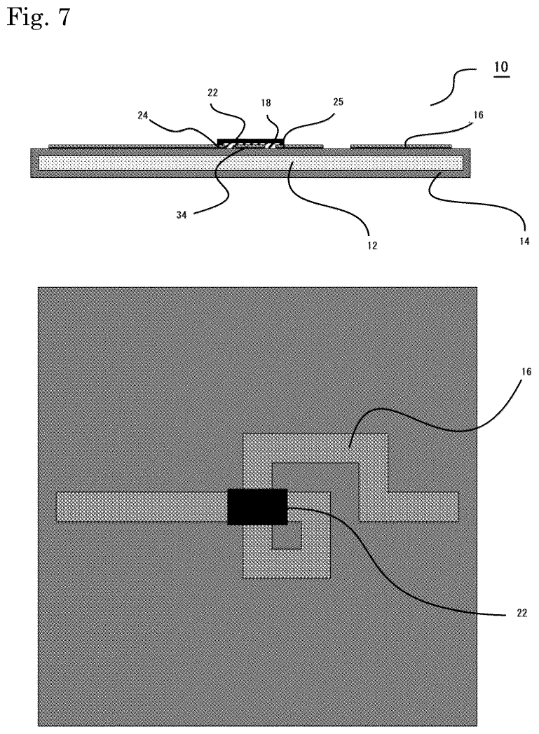

The infrared bolometer 10 according to the third embodiment of the present disclosure will be described with reference to FIG. 7. As shown in FIG. 7, in the bolometer of this embodiment, a mirror-cum-gate electrode 34 and wirings 16 (including a source electrode 24 and a drain electrode 25) are formed on a substrate having an insulating surface, and a first insulating film 18 is formed thereon. A carbon nanotube film 22, which is a light detection part, is formed on the first insulating film 18.

In the infrared bolometer 10 according to the third embodiment, a mirror-cum-gate electrode 34 that is spatially and electrically insulated from the carbon nanotube film 22 is provided below the carbon nanotube film 22, a voltage is applied between the source electrode 24 and the drain electrode 25, and a mirror-cum-gate electrode 34 and a drain electrode 25 are electrically short-circuited. As shown in FIG. 7, the drain side wiring passes under the carbon nanotube film when viewed from the power supply terminal side to form a gate electrode, and is further connected to the drain side end of the carbon nanotube film by wirings pattern that changes direction by an angle of 270°. In this embodiment, the portions of the wirings 16 that are in contact with the carbon nanotube film 22 serve as a source electrode 24 and a drain electrode 25. The source electrode 24 and the drain electrode 25 may be arranged inversely.

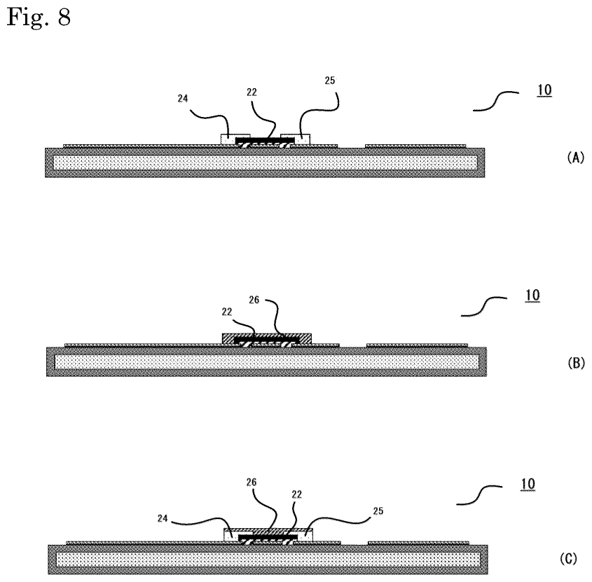

FIG. 8 shows variations of the infrared bolometer according to the third embodiment of the present disclosure. The infrared bolometer 10 shown in FIG. 8A is the same as the infrared bolometer shown in FIG. 7 except that the carbon nanotube film 22 is not in direct contact with the wirings 16, and has a source electrode 24 and a drain electrode 25 which are contact electrodes. The infrared bolometer 10 shown in FIG. 8B has a protective film 26 formed on the carbon nanotube film 22 in addition to the infrared bolometer shown in FIG. 7. The infrared bolometer 10 shown in FIG. 8C is the same as the infrared bolometer shown in FIG. 7 except that the carbon nanotube film 22 is not in direct contact with the wirings 16, and is connected to the wirings by the source electrode 24 and the drain electrode 25 which are contact electrodes, and additionally has a protective film 26 on the carbon nanotube film 22. The source electrode 24 and the drain electrode 25 may be arranged inversely.

### Fourth Embodiment

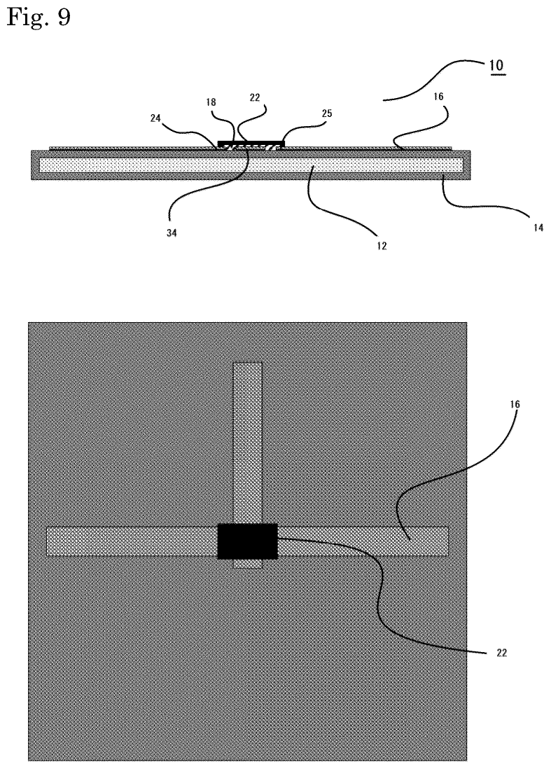

The infrared bolometer 10 according to the fourth embodiment of the present disclosure will be described with reference to FIG. 9. As shown in FIG. 9, in the bolometer of this embodiment, a mirror-cum-gate electrode 34 and wirings 16 (including a source electrode 24 and a drain electrode 25) are formed on a substrate having an insulating surface, and a first insulating film 18 is formed thereon. A carbon nanotube film 22, which is a light detection part, is formed on this first insulating film 18.

In the infrared bolometer 10 according to the fourth embodiment, a mirror-cum-gate electrode 34 that is spatially and electrically insulated from the carbon nanotube film 22 is provided below the carbon nanotube film 22, a voltage is applied between the source electrode 24 and the drain electrode 25, and another voltage is applied to the mirror-cum-gate electrode 34. As shown in FIG. 9, this structure has a three-terminal structure in which the source electrode, drain electrode, and gate electrode are independent, and a voltage can be applied to each electrode independently. In this embodiment, the portions of the wirings 16 that are in contact with the carbon nanotube film 22 serve as a source electrode 24 and a drain electrode 25. The source electrode 24 and the drain electrode 25 may be arranged inversely.

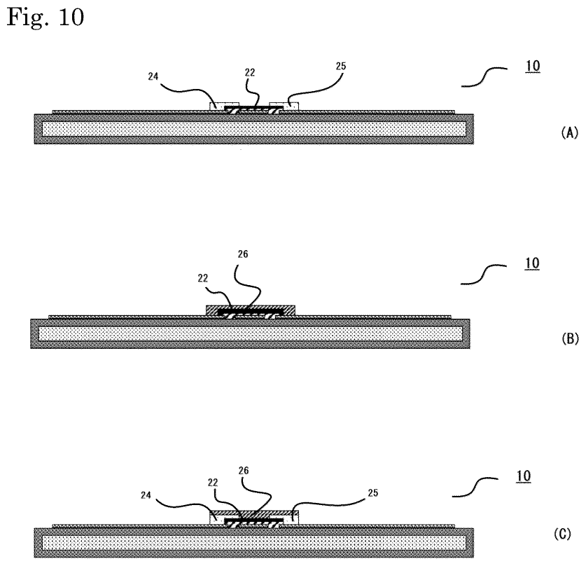

FIG. 10 shows variations of the infrared bolometer according to the fourth embodiment of the present disclosure. The infrared bolometer 10 shown in FIG. 10A is the same as the infrared bolometer shown in FIG. 9 except that the carbon nanotube film 22 is not in direct contact with the wirings 16, and has a source electrode 24 and a drain electrode 25 which are contact electrodes. The infrared bolometer 10 shown in FIG. 10B has a protective film 26 formed on the carbon nanotube film 22 in addition to the infrared bolometer shown in FIG. 9. The infrared bolometer 10 shown in FIG. 10C is the same as the infrared bolometer shown in FIG. 9 except that the carbon nanotube film 22 is not in direct contact with the wirings 16, and is connected to the wirings by the source electrode 24 and the drain electrode 25 which are contact electrodes, and additionally has a protective film 26 on the carbon nanotube film 22.

### [2] Infrared Bolometer Having a Gate Electrode Provided Above a Carbon Nanotube Film Via an Insulating Film (Top-Gate Type)

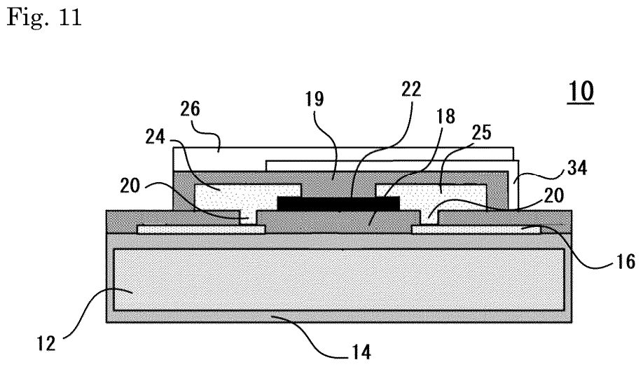

Another embodiment of the infrared bolometer of the present disclosure is a top-gate type infrared bolometer in which a gate electrode is formed on the carbon nanotube film via a second insulating film. A typical example of the structure of the infrared bolometer of this embodiment is shown in FIG. 11.

In the bolometer 10 of FIG. 11, wirings 16 are present on a substrate 12 covered with a resin film 14, a first insulating film 18 is present on the wirings 16, and a carbon nanotube film 22 is present on the first insulating film 18. Contact holes 20 are present in the insulating film 18. Two contact electrodes, i.e., a source electrode 24 and a drain electrode 25, are present so that the carbon nanotube film 22 and the wirings 16 are in electrical contact via the contact holes 20. The contact electrodes are present so as to cover a part of the carbon nanotube film 22 and a part of the wirings 16. A second insulating film 19 is present so as to cover the exposed part of the carbon nanotube film 22, a gate electrode (or a mirror-cum-gate electrode) 34 is present on the second insulating film 19, and a light absorbing film-cum-protective film 26 is present so as to cover the gate electrode 34.

In the infrared bolometer shown in FIG. 11, the carbon nanotube film 22 is also electrically connected to a source electrode 24 and a drain electrode 25 provided at a distance from each other. Although the source electrode 24 and the drain electrode 25 are shown as “contact electrode type” in FIG. 11, they may be either of “direct contact type” and “structure having a contact electrode part and a direct contact part” as in the case of the back-gate type bolometer.

In the top-gate type infrared bolometer, the structure described for the back-gate type infrared bolometer can be adopted except for the gate electrode being “on the carbon nanotube film” and the related structures thereof. As already described, the gate electrode may be present above a part or the whole of the upper part between the source electrode and the drain electrode, provided that the gate electrode is “above the carbon nanotube film”, and further, a part or the whole of the gate electrode 34 may be located outside the source electrode-drain electrode (S-D) and above the source electrode 24 (or the drain electrode 25) (see FIGS. 1D and 1E).

The voltage applied to the gate electrode 34 can be a voltage different from that between the source electrode 24 and the drain electrode 25, but the gate electrode 34 may be short-circuited to either the source electrode 24 or the drain electrode 25. Shorting the gate electrode 34 to either the source electrode 24 or the drain electrode 25 is more preferable because it facilitates integration as a detector. In addition, when the gate electrode is present only above the source electrode 24, it is preferable to give the gate electrode a potential different from that of the source electrode, and therefore it is preferable to short-circuit the gate electrode with the drain electrode. When the gate electrode is present only above the drain electrode, it is preferable to short-circuit the gate electrode with the source electrode. Even when a part of the gate electrode is present above the source electrode, it is usually preferable to short-circuit the gate electrode with the drain electrode. Conversely, when the gate electrode is present above the drain electrode, it is preferable to short-circuit the gate electrode with the source electrode.

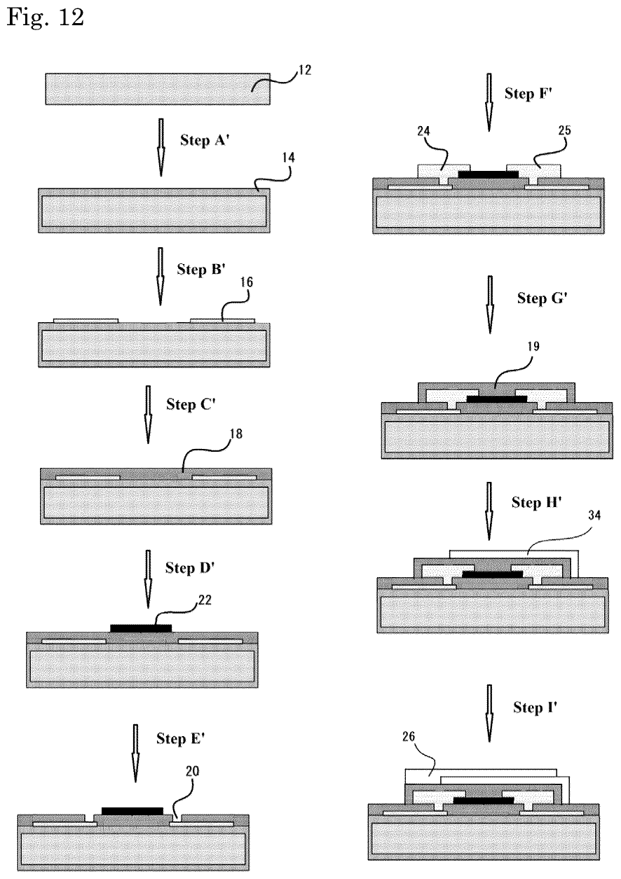

A specific example of each component of the infrared bolometer 10 shown in FIG. 11 will be described together with a manufacturing method shown in FIG. 12.

### [Step A′]

A substrate, at least a surface of the substrate on which an element is formed being insulating, is prepared (see step A above).

### [Step B′]

If necessary, wirings 16 are formed on the substrate. For the wiring, for example, a single metal such as titanium, gold, platinum, aluminum, copper, silver, tungsten and cobalt, or an alloy containing at least one of these metals can be used alone or in combination. The material of the wirings may be the same as or different from the material of the gate electrode, source electrode, and gate electrode. The wirings can be formed by patterning with a metal mask or the like as necessary, followed by deposition or printing.

### [Step C′]

When wirings are formed on the substrate, the first insulating film 18 is formed on the wiring. The material of the insulating film is not particularly limited, but examples thereof include silicon oxide (SiO₂) and silicon nitride (SiN). The method of forming the insulating film is not particularly limited, and can be appropriately selected according to the material used.

When steps B′ and C′ are performed, the substrate covered with the first insulating film 18 is regarded as “a substrate, at least a surface of the substrate on which an element is formed being insulating”.

### [Step D′]

A carbon nanotube film 22 is formed on the substrate. For the carbon nanotube film, see step D above.

### [Step E′]

If necessary, contact holes 20 for electrically connecting the wirings 16 to the carbon nanotube film 22 are formed in the first insulating film 18. See step E above.

### [Step F′]

If necessary, a source electrode 24 and a drain electrode 25 are formed so as to be in contact with the carbon nanotube film 22 and the wirings 16. See step F above.

### [Step G′]

A second insulating film 19 is formed on the carbon nanotube film 22. The material of the insulating film is not particularly limited, but examples thereof include silicon oxide (SiO₂) and silicon nitride (SiN). The method of forming the insulating film is not particularly limited, and can be appropriately selected according to the material used. In the top-gate type bolometer, since the insulating film 19 serves as the gate insulating film, the film thickness described for the gate insulating film in the back-gate type bolometer can be adopted.

### [Step H′]

A gate electrode 34 is formed on the second insulating film. The gate electrode can also serve as a mirror. For the gate electrode, for example, a single metal such as titanium, gold, platinum, aluminum, copper, silver, tungsten and cobalt, or an alloy containing at least one of these metals can be used alone or in combination. The material of the gate electrode may be the same as that of the wiring, source electrode, and drain electrode, or a different material may be used. The gate electrode can be formed by patterning with a metal mask or the like as necessary, and then by deposition or printing.

### [Step I′]

If necessary, a protective film 26 is formed so as to cover the exposed portion of the carbon nanotube film 22 and the gate electrode 34. For the protective film, see the above-mentioned step G.

The above describes the manufacturing method of the infrared bolometer 10 shown in FIG. 11. In the case of manufacturing a direct contact type bolometer (where the source electrode 24 and drain electrode 25 are in direct contact with the carbon nanotube film 22), when forming the first insulating film 18 on the source electrode 24 and the drain electrode 25 in step C′, (i) a portion of the wirings 16 (at least the portion that will become the source electrode 24 and the drain electrode 25) is masked, (ii) an insulating film is then formed, (iii) the mask is then removed to expose a portion of the wirings 16, and (iv) a carbon nanotube film 22 is then formed in step D′. As a result, the carbon nanotube film 22 is in direct contact with a part of the wirings 16, and the contact parts function as the source electrode 24 and the drain electrode 25.

As another manufacturing method, a method can be adopted in which, after forming the insulating film in step C′, the insulating film is removed by etching to expose a part of the wirings 16 (at least the part that will become the source electrode 24 and the drain electrode 25) before forming the carbon nanotube film 22, and the carbon nanotube film 22 is formed in step D′.

Furthermore, when manufacturing a structure having contact electrodes and direct contact part, the structure can be manufactured by forming a structure in which the carbon nanotube film is in direct contact with a portion of the wiring, and then forming the contact electrode.

### Examples of Top-Gate Type: Embodiment of Infrared Bolometers in which a Gate Electrode is Formed Above a Carbon Nanotube Film Via an Insulating Film

### Fifth Embodiment

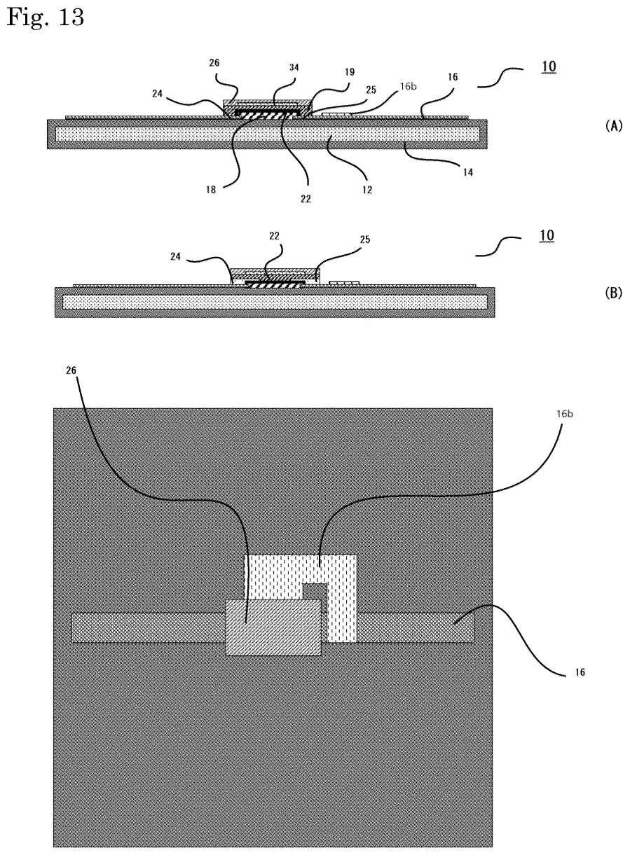

The infrared bolometer 10 according to the fifth embodiment of the present disclosure will be described with reference to FIG. 13. In the infrared bolometer 10 shown in FIG. 13A, wirings 16 (including source electrode 24 and drain electrode 25) is formed on a substrate having an insulating surface, and a first insulating film 18 is formed thereon. A carbon nanotube film 22, which is a light detection part, is formed on the first insulating film 18, a second insulating film 19 is formed on the carbon nanotube film 22, and a mirror-cum-gate electrode 34 is formed on the second insulating film 19. Then, a light absorbing film-cum-protective film 26 is formed on the mirror-cum-gate electrode 34.

In the infrared bolometer 10 according to the fifth embodiment, a mirror-cum-gate electrode 34, which is spatially and electrically insulated from the carbon nanotube film 22, is provided on the carbon nanotube film 22, and a voltage is applied between the source electrode 24 and the drain electrode 25, and the mirror-cum-gate electrode 34 and the drain electrode 25 are electrically short-circuited. As shown in FIG. 13, the wirings on the drain side when viewed from the power supply terminal side is connected (directly or through a contact hole) to a gate wiring 16b that leads to a gate electrode before being connected to the drain side end of the carbon nanotube film, the gate wiring 16b extends perpendicular to the wirings 16, then turns 180° and extends to the top of the carbon nanotube film to form the gate electrode. In this embodiment, the contact portion of the wirings 16 with the carbon nanotube film 22 becomes the source electrode 24 and the drain electrode 25. The source electrode 24 and the drain electrode 25 may be arranged inversely. In this embodiment, since there is a light absorbing film on the mirror, sufficient heat is transmitted to the nanotube film.

The infrared bolometer 10 shown in FIG. 13B has, in addition to the infrared bolometer shown in FIG. 13A, a carbon nanotube film 22 and wirings 16 in direct contact with each other, and also has a source electrode 24 and a drain electrode 25 which are contact electrodes. The source electrode 24 and the drain electrode 25 may be arranged inversely.

### Sixth Embodiment

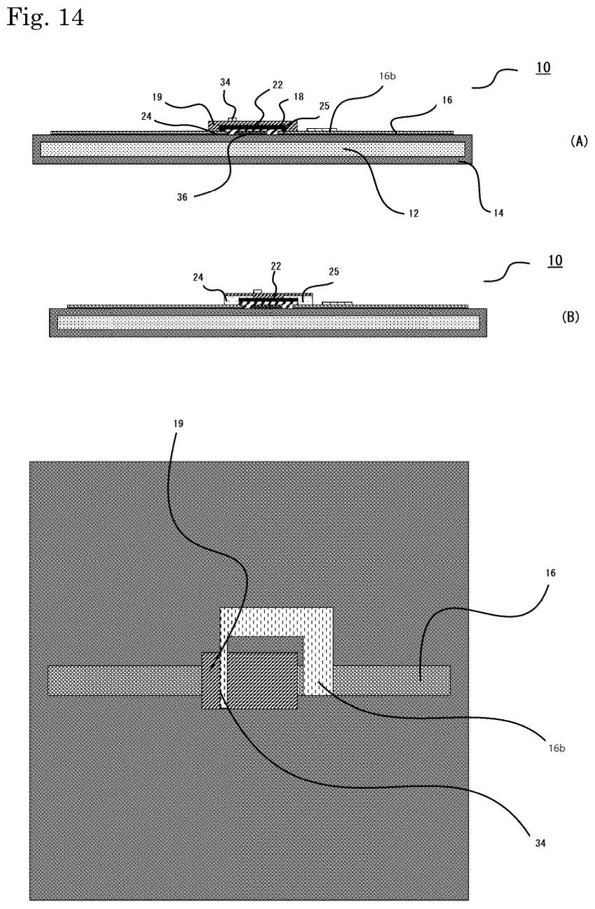

The infrared bolometer 10 according to the sixth embodiment of the present disclosure will be described with reference to FIG. 14. The infrared bolometer 10 shown in FIG. 14A has a mirror 36 and wirings 16 (including a source electrode 24 and a drain electrode 25) formed on a substrate having an insulating surface, and a first insulating film 18 formed thereon. A carbon nanotube film 22, which is a light detection part, is formed on the first insulating film 18, a second insulating film 19 is formed on the carbon nanotube film 22, and a gate electrode 34 is formed on the second insulating film 19.

In the infrared bolometer 10 of the sixth embodiment, a gate electrode 34 that is spatially and electrically insulated from the carbon nanotube film 22 is provided on the carbon nanotube film 22, a voltage is applied between the source electrode 24 and the drain electrode 25, and the gate electrode 34 and the drain electrode 25 are electrically short-circuited. The electrical connection of the gate electrode is the same as in the fifth embodiment, but the gate length (the length of the gate electrode in the source-drain direction) is shorter than the length between the source and drain. This is to reduce light blocking by the gate electrode and ensure that the mirror 36 functions properly. It is preferable to make the gate length shorter than the length of the mirror 36 in the source-drain direction, and more preferably to make it ½ or less. Alternatively, as shown in FIG. 14A, it is possible to arrange the gate electrode so that it does not overlap with the mirror. In this case, the position of the gate electrode 34 does not have to be between the source and drain, and at least a part of the gate electrode 34 may overlap with the source electrode.

In this embodiment, the portions of the wirings 16 that are in contact with the carbon nanotube film 22 serve as a source electrode 24 and a drain electrode 25. The source electrode 24 and the drain electrode 25 may be arranged inversely.

The infrared bolometer 10 shown in FIG. 14B has a source electrode 24 and a drain electrode 25 in contact with the carbon nanotube film 22 in addition to the infrared bolometer shown in FIG. 14A. The source electrode 24 and the drain electrode 25 may be arranged inversely.

### Seventh Embodiment

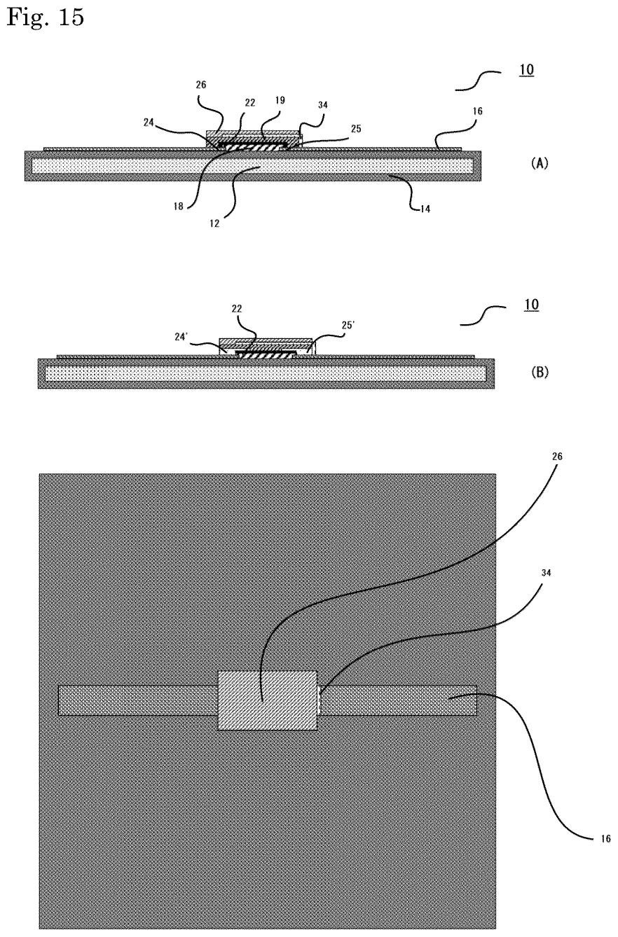

The infrared bolometer 10 according to the seventh embodiment of the present disclosure will be described with reference to FIG. 15. In the infrared bolometer 10 shown in FIG. 15A, wirings 16 (including source electrode 24 and drain electrode 25) is formed on a substrate having an insulating surface, and a first insulating film 18 is formed thereon. A carbon nanotube film 22, which is a light detection part, is formed on the first insulating film 18, a second insulating film 19 is formed on the carbon nanotube film 22, and a mirror-cum-gate electrode 34 is formed on the second insulating film 19. A light absorbing film-cum-protective film 26 is then formed on the mirror-cum-gate electrode 34. In this embodiment, since the light absorbing film is on the mirror, sufficient heat is transferred to the nanotube film.

In the infrared bolometer 10 according to the seventh embodiment, a mirror-cum-gate electrode 34, which is spatially and electrically insulated from the carbon nanotube film 22, is provided on the carbon nanotube film 22, a voltage is applied between the source electrode 24 and the drain electrode 25, and the mirror-cum-gate electrode 34 and the drain electrode 25 are electrically short-circuited. As shown in FIG. 15, a gate wiring 16b is connected (directly or through a contact hole) to the wiring on the drain side when viewed from the power supply terminal side before it connects to the drain side end of the carbon nanotube film, and the gate wiring 16b extends to the top of the carbon nanotube film without changing direction to form a gate electrode. In this embodiment, the portions of the wirings 16 that are in contact with the carbon nanotube film 22 serve as a source electrode 24 and a drain electrode 25. The source electrode 24 and the drain electrode 25 may be arranged inversely.

The infrared bolometer 10 shown in FIG. 15B differs from the infrared bolometer shown in FIG. 15A in that the carbon nanotube film 22 is not in direct contact with the wirings 16 and has a source electrode 24′ and a drain electrode 25′ which are contact electrodes. The source electrode 24 and the drain electrode 25 may be arranged inversely.

### Eighth Embodiment

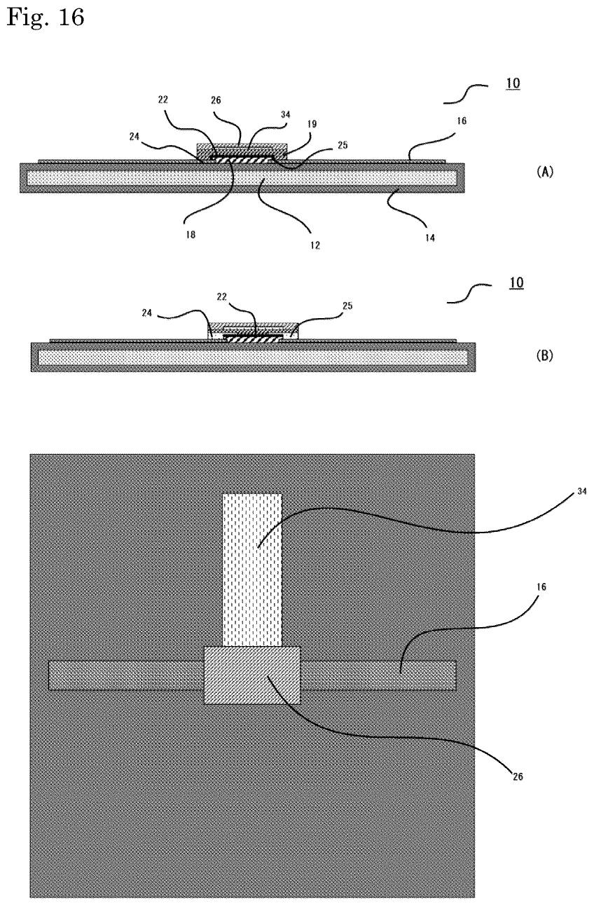

The infrared bolometer 10 according to the eighth embodiment of the present disclosure will be described with reference to FIG. 16. In the infrared bolometer 10 shown in FIG. 16A, wirings 16 (including source electrode 24 and drain electrode 25) is formed on a substrate having an insulating surface, a first insulating film 18 is formed thereon. A carbon nanotube film 22, which is a light detection part, is formed on the first insulating film 18, a second insulating film 19 is formed on the carbon nanotube film 22, and a mirror-cum-gate electrode 34 is formed on the second insulating film 19. A light absorbing film-cum-protective film 26 is then formed on the mirror-cum-gate electrode 34. In this embodiment, since the light absorbing film is on the mirror, sufficient heat is transferred to the nanotube film.

In the infrared bolometer 10 according to the eighth embodiment, a mirror-cum-gate electrode 34 that is spatially and electrically insulated from the carbon nanotube film 22 is provided on the carbon nanotube film 22, a voltage is applied between the source electrode 24 and the drain electrode 25, and another voltage is applied to the mirror/gate electrode 34. As shown in FIG. 16, this structure has a three-terminal structure in which the source electrode, drain electrode, and gate electrode are independent, and voltages can be applied to each electrode independently. In this embodiment, the portions of the wirings 16 that are in contact with the carbon nanotube film 22 serve as a source electrode 24 and a drain electrode 25. The source electrode 24 and the drain electrode 25 may be arranged inversely.

The infrared bolometer 10 shown in FIG. 16B differs from the infrared bolometer shown in FIG. 16A in that the carbon nanotube film 22 is not in direct contact with the wirings 16 and has a source electrode 24 and a drain electrode 25 which are contact electrodes. The source electrode 24 and the drain electrode 25 may be arranged inversely.

### Nineth Embodiment

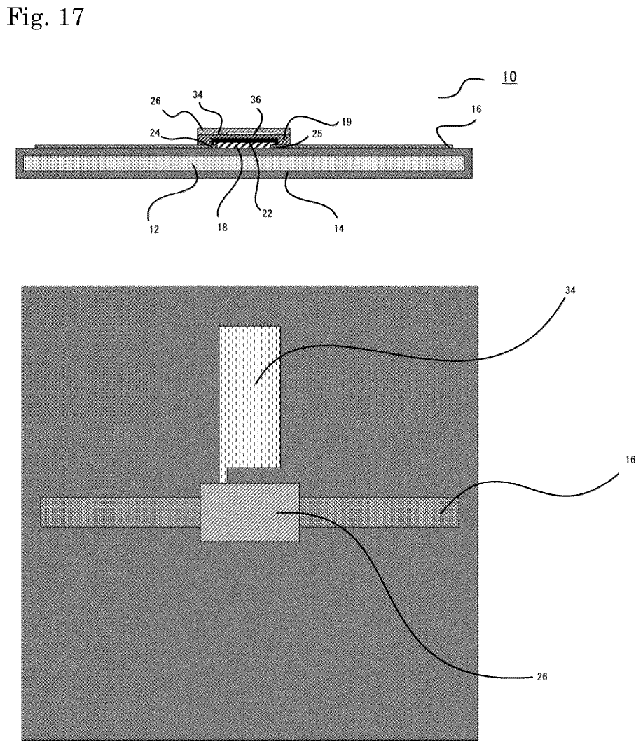

The infrared bolometer 10 according to the nineth embodiment of the present disclosure will be described with reference to FIG. 17. In the infrared bolometer 10 shown in FIG. 15, wirings 16 (including source electrode 24 and drain electrode 25) is formed on a substrate having an insulating surface, and a first insulating film 18 is formed thereon. A carbon nanotube film 22, which is a light detection part, is formed on the first insulating film 18, a second insulating film 19 is formed on the carbon nanotube film 22, a gate electrode 34 and a mirror 36 are formed on the second insulating film 19, and a light absorbing film-cum-protective film 26 is further formed thereon. In this embodiment, since the light absorbing film is on the mirror, sufficient heat is transferred to the nanotube film.

In the infrared bolometer 10 according to the ninth embodiment, a gate electrode 34 that is spatially and electrically insulated from the carbon nanotube film 22 is provided on the carbon nanotube film 22, and a voltage is applied between the source electrode 24 and the drain electrode 25, and another voltage is applied to the gate electrode 34. In this structure, the electrical connection of the gate electrode is the same as in the eighth embodiment, but the gate length (the length of the gate electrode in the source-drain direction) is made shorter than the source-drain length, and a mirror 36 is provided. In addition, the position of the gate electrode 34 does not have to be between the source and drain, and at least a portion of the gate electrode 34 may be in a position that overlaps with the source electrode. In this embodiment, the portions of the wirings 16 that are in contact with the carbon nanotube film 22 serve as a source electrode 24 and a drain electrode 25. The source electrode 24 and the drain electrode 25 may be arranged inversely.

### Tenth Embodiment

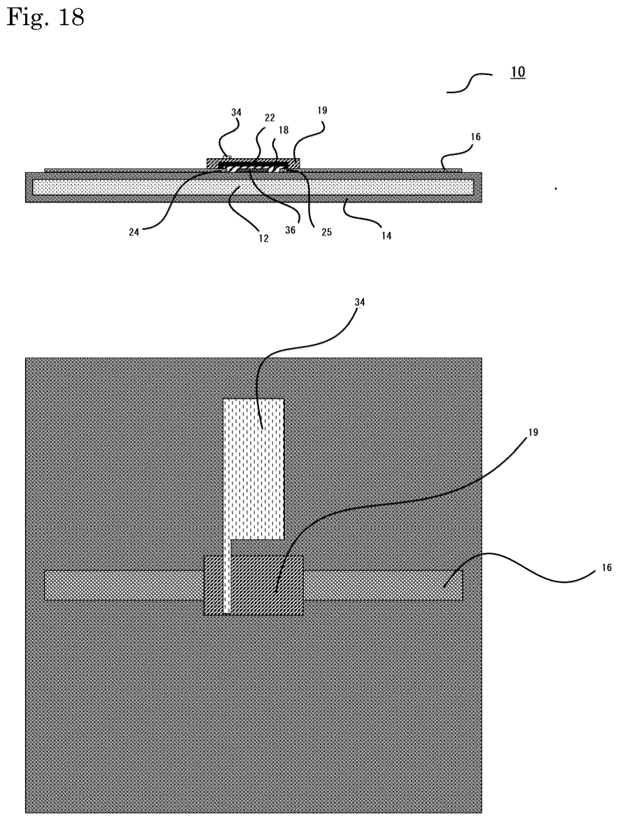

An infrared bolometer 10 according to a tenth embodiment of the present disclosure will be described with reference to FIG. 18. In the infrared bolometer 10 shown in FIG. 18, a mirror 36 and wirings 16 (including a source electrode 24 and a drain electrode 25) are formed on a substrate having an insulating surface, and a first insulating film 18 is formed thereon. A carbon nanotube film 22, which is a light detection part, is formed on the first insulating film 18, a second insulating film 19 is formed on the carbon nanotube film 22, and a gate electrode 34 is formed on the second insulating film 19.

In the infrared bolometer 10 according to the tenth embodiment, a gate electrode 34, which is spatially and electrically insulated from the carbon nanotube film 22, is provided on the carbon nanotube film 22, a voltage is applied between the source electrode 24 and the drain electrode 25, and another voltage is applied to the gate electrode 34. In this structure, the electrical connection of the gate electrode is the same as in the eighth embodiment, but the gate length (the length of the gate electrode in the source-drain direction) is shorter than the length between the source and drain. This is to reduce light blocking by the gate electrode and ensure that the mirror 36 functions properly. It is preferable to make the gate length shorter than the length of the mirror 36 in the source-drain direction, and more preferably to make it ½ or less. Alternatively, as shown in FIG. 18, it is possible to arrange the gate electrode so that it does not overlap with the mirror. The position of the gate electrode 34 does not have to be between the source and drain, and may be in a position where at least a part of the gate electrode 34 overlaps with the source electrode. In this embodiment, the portions of the wirings 16 that are in contact with the carbon nanotube film 22 serve as a source electrode 24 and a drain electrode 25. The source electrode 24 and the drain electrode 25 may be arranged inversely.

In the above description, it is assumed that the carbon nanotube film is a p-type semiconductor, but the same configuration can be used for an n-type semiconductor. When the gate electrode is short-circuited with the source electrode or the drain electrode, for example, the gate electrode and the source electrode can be short-circuited.

Although one cell (single element) of a bolometer was shown above, any element structure and array structure that can be used for a bolometer can be applied without any particular restrictions. For example, bolometer elements can be arranged in an array to form a bolometer array. An array in which multiple elements are arranged two-dimensionally, such as that used in an image sensor, may also be used.

The bolometer using the carbon nanotube film of the present disclosure can be particularly suitably used for detecting electromagnetic waves having a wavelength of, for example, 0.7 μm to 1 mm, in addition to infrared light. Examples of electromagnetic waves falling within this wavelength range include infrared light and terahertz waves.

### EXAMPLES

The present disclosure will be described further in detail by way of examples below, but the present disclosure should not be limited by the following examples.

### Example 1

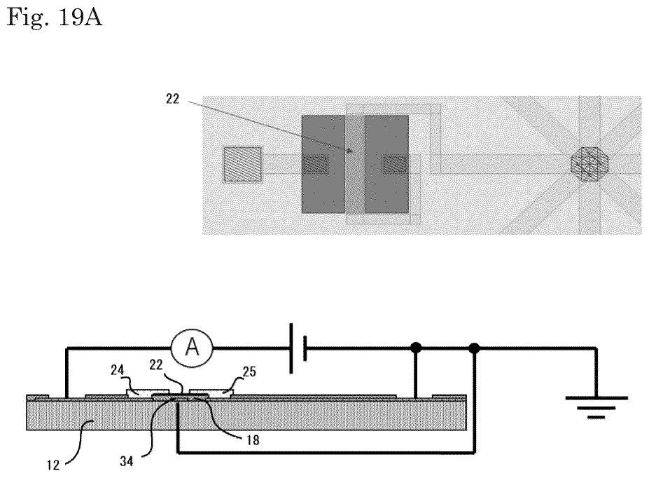

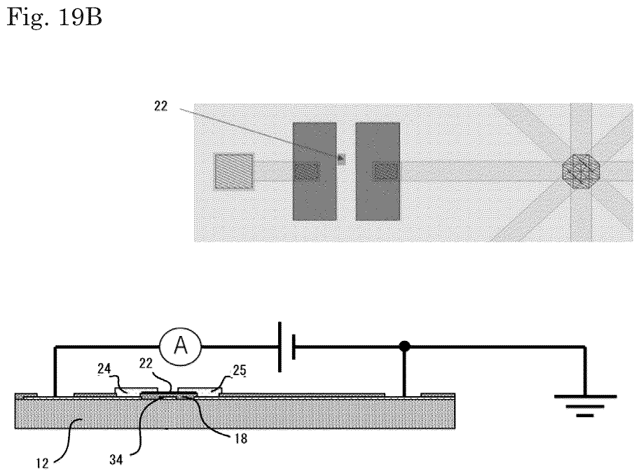

An infrared bolometer with the structure shown in FIG. 19A was prepared. The mirror-cum-gate electrode 34 and the drain electrode 25 were electrically short-circuited. A voltage was applied between the source electrode 24 and the drain electrode 25 and the current was measured.

### Comparative Example 1

An infrared bolometer with the structure shown in FIG. 19B was prepared. The mirror-cum-gate electrode 34 simply functions as a mirror, and the potential is floating. A voltage was applied between the source electrode 24 and the drain electrode 25 and the current was measured.

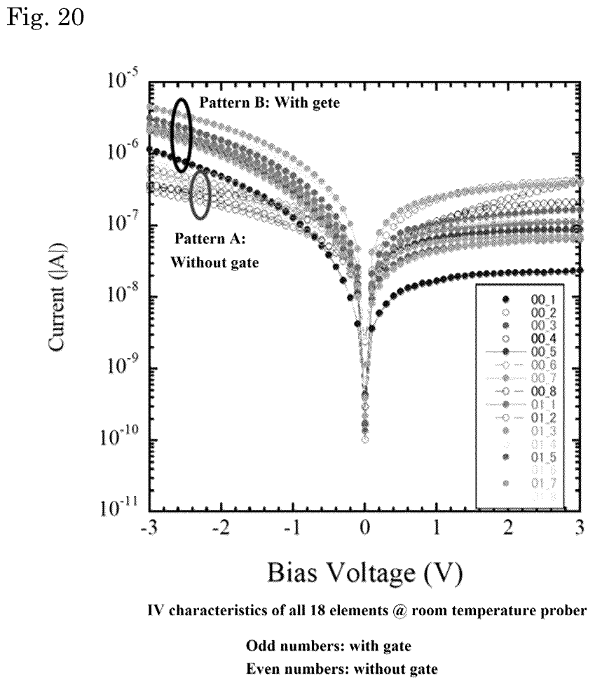

FIG. 20 shows the current-voltage curves of Example 1 and Comparative Example 1. It was confirmed that when a gate voltage was applied to the carbon nanotube film, the current was increased and the resistance value of the infrared bolometer was decreased compared to when no gate voltage was applied.

Although the present disclosure has been described above with reference to the embodiments and Examples, the present disclosure is not limited to the above-mentioned embodiments and Examples. Various modifications that can be understood by one skilled in the art can be made to the configuration and details of the present disclosure within the scope of the present disclosure.

### [Supplementary Note 1]

An infrared bolometer comprising:
a source electrode and a drain electrode arranged at a distance from each other;
a carbon nanotube film, which is a light detection part, that is present between the two electrodes and that overlaps at least partially with and is in electrical contact with the two electrodes; and
a gate electrode that is provided above or below the carbon nanotube film via an insulating film.

### (Supplementary Note 2)

The infrared bolometer according to supplementary note 1, wherein a voltage is applied between the source electrode and the drain electrode, and a voltage is applied independently to the gate electrode.

### (Supplementary Note 3)

The infrared bolometer according to supplementary note 1, wherein a voltage is applied between the source electrode and the drain electrode, and the gate electrode is electrically short-circuited to either the source electrode or the drain electrode.

### (Supplementary Note 4)

The infrared bolometer according to any of supplementary notes 1 to 3, wherein the gate electrode is formed below the carbon nanotube film via a first insulating film.

### (Supplementary Note 5)

The infrared bolometer according to any of supplementary notes 1 to 3, wherein the gate electrode is formed above the carbon nanotube film via a second insulating film.

### (Supplementary Note 6)

The infrared bolometer according to any of the preceding supplementary notes, wherein the source electrode and the drain electrode, or wirings for supplying power to these electrodes, are formed on a substrate having an insulating surface.

### (Supplementary Note 7)

The infrared bolometer according to supplementary note 4, wherein (i) the source electrode and the drain electrode, or wirings for supplying power to these electrodes, and (ii) the gate electrode are formed on a substrate having an insulating surface.

### (Supplementary Note 8)

The infrared bolometer according to any of the preceding supplementary notes, wherein the gate electrode also serves as a mirror.

### (Supplementary Note 9)

A method for manufacturing an infrared bolometer, comprising:
preparing a substrate, at least a surface of the substrate on which an element is formed being insulating;
forming a gate electrode on the substrate;
forming a first insulating film on the gate electrode; and forming a carbon nanotube film on the first insulating film.

### (Supplementary Note 10)

A method for manufacturing infrared bolometer comprising:
preparing a substrate, at least a surface of the substrate on which an element is formed being insulating;
forming a carbon nanotube film on the substrate;
forming a second insulating film above the carbon nanotube film; and forming a gate electrode on the second insulating film.

### (Supplementary Note 11)

The infrared bolometer according to any of the preceding supplementary notes, wherein the insulating film has contact holes for contacting the wirings with the source electrode and the drain electrode.

### (Supplementary Note 12)

The infrared bolometer according to any of the preceding supplementary notes, wherein the substrate having an insulating surface is a substrate whose surface is covered with a resin film,

### (Supplementary Note 13)

The infrared bolometer according to any of the preceding supplementary notes, further comprising a protective film above the carbon nanotube film.

### (Supplementary Note 14)

The infrared bolometer according to any of the preceding supplementary notes, wherein the protective film also serves as a light absorbing film.

### EXPLANATION OF REFERENCE

10 Bolometer
12 Substrate
14 Resin film
16 Wiring
16b Gate wiring
18 First insulating film
19 Second insulating film
20 Contact hole
22 Carbon nanotube film
24 Source electrode
25 Drain electrode
24a, 25a Contact electrode part
24b, 25b Direct contact part
26 Protective film (or light absorbing film-cum-protective film)
34 Gate electrode (or mirror-cum-gate electrode)
36 Mirror

1. An infrared bolometer comprising:
a source electrode and a drain electrode arranged at a distance from each other;
a carbon nanotube film, which is a light detection part, that is present between the two electrodes and that overlaps at least partially with and is in electrical contact with the two electrodes; and
a gate electrode that is provided above or below the carbon nanotube film via an insulating film.

2. The infrared bolometer according to claim 1, wherein a voltage is applied between the source electrode and the drain electrode, and a voltage is applied independently to the gate electrode.

3. The infrared bolometer according to claim 1, wherein a voltage is applied between the source electrode and the drain electrode, and the gate electrode is electrically short-circuited to either the source electrode or the drain electrode.

4. The infrared bolometer according to claim 1, wherein the gate electrode is formed below the carbon nanotube film via a first insulating film.

5. The infrared bolometer according to claim 1, wherein the gate electrode is formed above the carbon nanotube film via a second insulating film.

6. The infrared bolometer according to claim 1, wherein the source electrode and the drain electrode, or wirings for supplying power to these electrodes, are formed on a substrate having an insulating surface.

7. The infrared bolometer according to claim 4, wherein (i) the source electrode and the drain electrode, or wirings for supplying power to these electrodes, and (ii) the gate electrode are formed on a substrate having an insulating surface.

8. The infrared bolometer according to claim 1, wherein the gate electrode also serves as a mirror.

9. A method for manufacturing an infrared bolometer, comprising:
preparing a substrate, at least a surface of the substrate on which an element is formed being insulating;
forming a gate electrode on the substrate;
forming a first insulating film on the gate electrode; and
forming a carbon nanotube film on the first insulating film.

10. A method for manufacturing infrared bolometer comprising:
preparing a substrate, at least a surface of the substrate on which an element is formed being insulating;
forming a carbon nanotube film on the substrate;
forming a second insulating film above the carbon nanotube film; and
forming a gate electrode on the second insulating film.
